(19) United States
(12) Patent Application Publication
(10) Pub. No.: US 2015/0378342 A1
(43) Pub. Date: Dec. 31, 2015

(54) COMMAND DATA GENERATION METHOD, POSITIONING APPARATUS, LITHOGRAPHY APPARATUS, AND ARTICLE MANUFACTURING METHOD

(71) Applicant: CANON KABUSHIKI KAISHA, Tokyo (JP)

(72) Inventor: Hirohito Ito, Funabashi-shi (JP)

(21) Appl. No.: 14/749,357

(22) Filed: Jun. 24, 2015

(30) Foreign Application Priority Data
Jun. 27, 2014 (JP) 2014-133284

(51) Int. Cl. G05B 19/19; H01L 21/265; H01L 21/263

(52) U.S. Cl. CPC G05B 19/19; H01L 21/2633; H01L 21/265; G05B 2219/37372

(57) ABSTRACT

A command data generation method includes the steps of acquiring, by performing iterative learning control on a moving member, a first command data set for moving the moving member along a first trajectory, the first command data set including data corresponding to an acceleration section, a constant speed section and a deceleration section of the moving member, and generating a second command data set for driving the moving member along a second trajectory by using a part of data for the constant speed section in the first command data set.

### BACKGROUND OF THE INVENTION

1. Field of the Invention

One disclosed aspect of the embodiments relates to a command data generation method, a positioning apparatus, a lithography apparatus, and an article manufacturing method.

2. Description of the Related Art

In order to control positioning of a stage with high precision, a method is disclosed in which a control command pattern acquired by iterative learning control may be used for positioning control of a stage (Japanese Patent Laid-Open No. 2009-205641). The iterative learning control is a control method in which an output acquired by one trial is used to determine input of the next trial. Applying this to a stage, a control command pattern may be determined which causes a small control error with respect to a target trajectory of a stage. Performing learning control in advance may allow correction of a control error which is reproducible and difficult to be included in a control model.

However, for a new target trajectory of a stage to be driven, learning control may be required again to determine a control command corresponding to the new target trajectory. Applying it to a stage in a lithography apparatus may cause a problem of a throughput reduced because of the time required for the learning control.

Japanese Patent Laid-Open No. 2-294703 discloses a method which extracts a control command pattern the most similar to a new operation pattern from a plurality of prestored control command patterns so that a control command pattern may be acquired by performing a low number of iterative trials.

The control method disclosed in Japanese Patent Laid-Open No. 2-294703 allows reduction of the time required for acquisition of a control command pattern corresponding to a new operation pattern. However, in order to acquire a pattern causing a small control error in a shorter time period, storage of more control command patterns may be required, imposing a higher load on memory.

### SUMMARY OF THE INVENTION

One of the examples of the present invention provides a command data generation method which allows generation of command data for driving a moving member along a new trajectory not through driving under learning control over the new trajectory.

A command data generation method includes the steps of acquiring, by performing iterative learning control on a moving member, a first command data set for moving the moving member along a first trajectory, the first command data set including data corresponding to an acceleration section, a constant speed section and a deceleration section of the moving member, and generating a second command data set for driving the moving member along a second trajectory by using a part of data for the constant speed section in the first command data set.

Further features of the present invention will become apparent from the following description of exemplary embodiments with reference to the attached drawings.

### BRIEF DESCRIPTION OF THE DRAWINGS

FIG. 1 illustrates a configuration of a drawing apparatus.

FIGS. 2A to 2C illustrate trajectories of a stage.

FIG. 3 is a flowchart illustrating a control data generation method.

FIGS. 4A and 4B are diagrams for explaining learning control.

FIG. 5 illustrates control data acquired by learning control.

FIGS. 6A and 6B are diagrams for explaining a control data generation method.

FIG. 7 is a diagram for explaining connections of switching sections.

FIGS. 8A and 8B are diagrams for explaining control data according to a second embodiment.

### DESCRIPTION OF THE EMBODIMENTS

### First Embodiment

### Apparatus Configuration

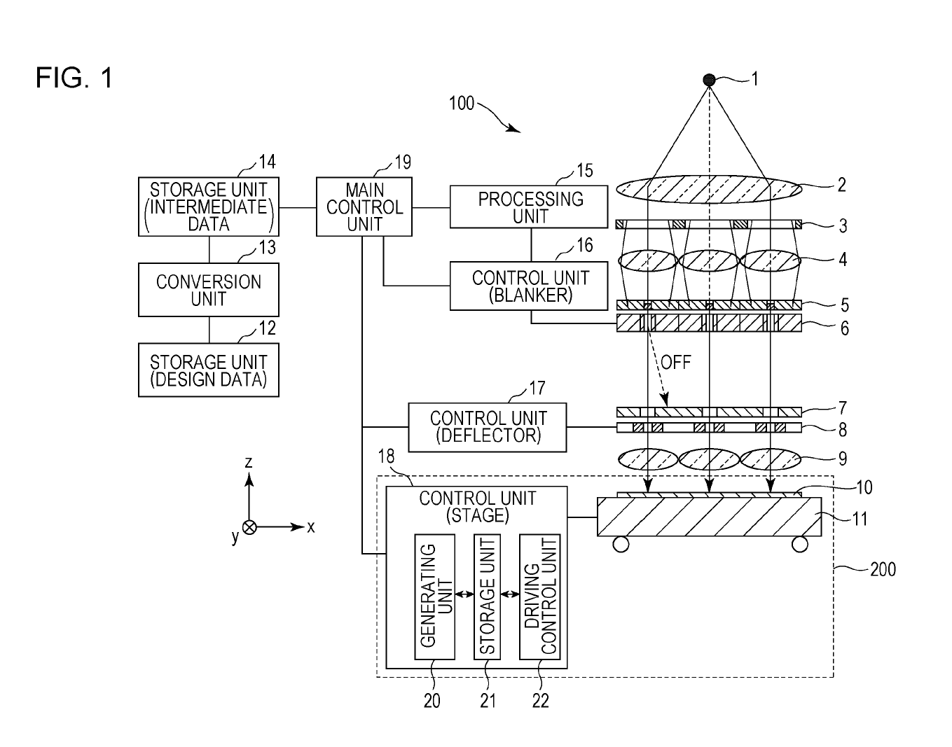

A first embodiment of the present invention relates to a drawing apparatus (lithography apparatus) 100 configured to form a latent image pattern on a wafer by using a plurality of electron beams. FIG. 1 illustrates a configuration of the drawing apparatus 100. An electron source 1 emits electrons, and a collimator lens 2 which is an electrostatic lens causes the plurality of trajectories of electrons emitted by the electron source 1 to be substantially parallel with each other.

An aperture 3 uses a plurality of two-dimensionally aligned openings of the aperture 3 to divide the electron beam having passed through the collimator lens 2 into a plurality of electron beams. Lenses 4 having openings corresponding to the openings of the aperture 3 transmit electron beams having passed through the lenses 4 toward an aperture array 5 having a plurality of openings. A blanker 6 having a plurality of electrodes aligned at positions corresponding to the aperture array 5 is capable of separately deflecting trajectories of electron beams before passing through the blanker 6. A diaphragm 7 having a plurality of openings blocks electron beams which are not deflected by the blanker 6 and allows the electron beams which are not deflected to pass through.

A deflector 8 collectively deflects electron beams which are not blocked by the blanker 6 and diaphragm 7 in an X-axis direction. Thus, one electron beam may be used to draw with a drawing width based on a deflection width of the deflector 8. The electron beam having passed through the deflector 8 is reduction-projected onto a wafer 10 through an objective lens 9. A stage 11 (moving member) supports the wafer 10 and is driven in X-axis, Y-axis, and Z-axis directions.

A storage unit 12 stores data of a desired drawing pattern designed by a user. A converting unit 13 converts data stored in the storage unit 12 to bitmap data. The Bitmap data here are data representing the number of tones of an electron beam to be irradiated to one pixel. A storage unit 14 stores the bitmap data generated by the converting unit 13.

A main control unit 19 is connected to the storage unit 14, a processing unit 15, a control unit 16, a control unit 17, and a control unit 18. The processing unit 15 uses bitmap data which is transferred from the storage unit 14 via the main control unit 19 to generate data for instructing to control over the control unit 16 for the blanker 6. The control unit 16 selectively deflects an electron beam at a preset time in response to a command from the processing unit 15. The control unit 17 controls the deflector 8 and deflects an electron beam at a preset time. In other words, the control unit 16 and control unit 17 control time points for irradiation and non-irradiation and an irradiation position of an electron beam to the wafer 10.

In the drawing apparatus 100, a stage apparatus (positioning apparatus) 200 has the control unit 18 and the stage 11. The control unit 18 for the stage 11 has functions of a generating unit 20, a storage unit (memory) 21, and a drive control unit 22. The control unit 18 has a CPU and a memory and uses control data acquired by driving to perform iterative learning control (first command data set) (hereinafter, called learning control) on the stage 11 based on one target trajectory to generate control data corresponding to another target trajectory (second command data set). The target trajectory refers to data describing positions of the stage 11 for an elapsed time.

The control data may be data describing a relationship between an elapsed time and command values (command information) or a relationship between positions of the stage 11 and command values. The command value may be any amount of force to be applied to the stage 11 or any amount of electricity such as an amount of current to be applied to an actuator for generating the force as far as the command value corresponds to an amount for controlling a force to be applied to the stage 11 through an actuator (not illustrated), which will be described below.

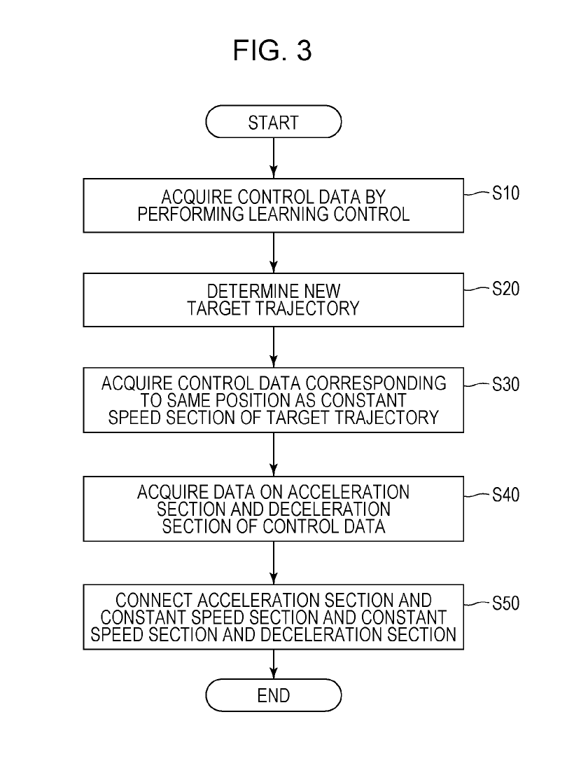

The storage unit 21 stores control data acquired by performing learning control and driving the stage 11. The storage unit 21 stores a temporary correction amount required for performing the corresponding learning control. The storage unit 21 stores a program illustrated in the flowchart in FIG. 3, which will be described below, for generating control data by the generating unit 20.

The storage unit 21 further stores data regarding a target trajectory describing positions of the stage 11 corresponding to times, which are generated by the generating unit 20, and control data corresponding to a new target trajectory. The drive control unit 22 has a circuit having feedback and feedforward functions. In order for the drive control unit 22 to position the stage 11, the drive control unit 22 drives the stage 11 based on control data acquired by driving iterative learning control and control data corresponding to another target trajectory, which are generated from the control data.

The main control unit 19 instructs time points for those controls to the control unit 16, control unit 17 and control unit 18 based on a measurement result of an interferometer (not illustrated) configured to measure a position of the stage 11. Thus, irradiation/non-irradiation of an electron beam and the motion of the wafer 10 are synchronously controlled so that a latent image of a drawing pattern may be formed on the wafer 10.

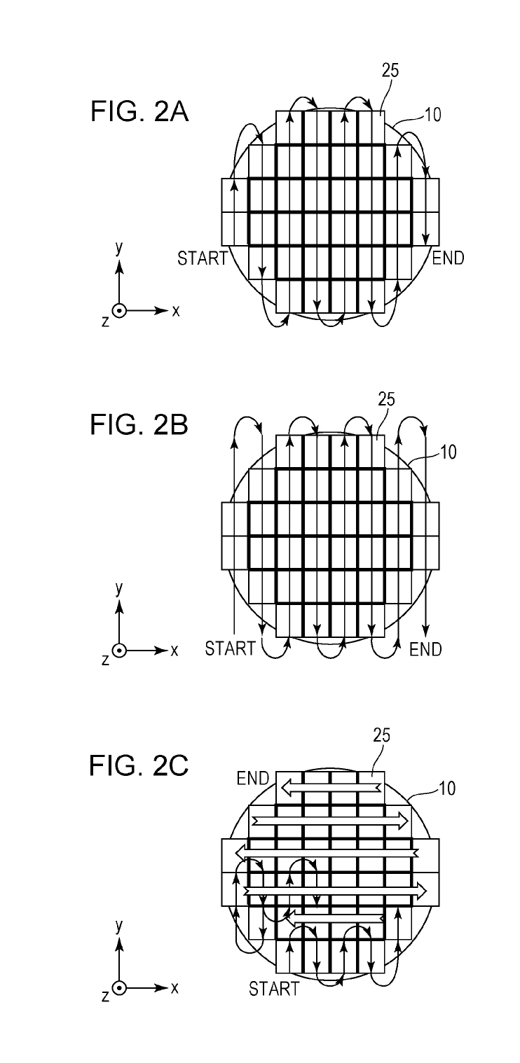

FIGS. 2A to 2C illustrate trajectories of the stage 11 in drawing processing. FIG. 2A illustrates how an operation is repeated including scanning in a y axis direction, then moving the stage 11 by a drawing width in an x axis direction and scanning reversely in the y axis direction in turn. The moving distance in the y axis direction may vary in accordance with the number of chips 25 aligned in the y axis direction.

FIG. 2B illustrates how a reciprocating motion of the stage 11 substantially similar to that in FIG. 2A is repeated. However, the operation in FIG. 2B is different from the operation in FIG. 2A in that the moving distance in the y axis direction is independent of the number of chips 25 aligned in the y axis direction.

FIG. 2C illustrates how drawing is performed by each one of the chips 25. FIG. 2C illustrates how an operation is repeated including scanning in the y axis direction by substantially an equal length of one chip 25 in the y axis direction, moving the stage 11 by a drawing width in the x axis direction and reversely scanning in the y axis direction for one chip in turn.

In addition to the driving for drawing, the stage 11 may sometimes be driven for a relatively long distance. For example, the stage 11 may be driven between a position where an electron beam is irradiated and a position detected by an alignment optical system (not illustrated) configured to detect an alignment mark on the wafer, for example, or between a position where an electron beam is irradiated and a position of transfer performed by a transfer hand (not illustrated) of the wafer.

In the drawing apparatus 100, the stage 11 is driven at a maximum acceleration and a maximum speed for an improved throughput within any drive position range. In other words, the stage 11 is accelerated at a maximum acceleration. When the speed reaches a maximum speed, the speed is maintained, and the stage 11 is driven at the uniform speed. Then, the stage 11 is again decelerated at the maximum acceleration in the reverse direction. Thus, the times required for the acceleration and deceleration do not substantially change even when the trajectories (driving position) and a total driving distance for driving the stage 11 change.

### Control Data Generation Method

Next, a control data generation method using the generating unit 20 will be described. FIG. 3 is a flowchart illustrating a generation procedure for using a part of one control data set acquired by learning control to generate another control data set. The generating unit 20 executes a program relating to the procedure illustrated in FIG. 3. The generation procedure may be roughly divided into a process for acquiring control data by performing learning control on the stage 11 for one target trajectory (S10) and a process for generating control data for a new target trajectory based on the acquired control data (S20 to S50). Accordingly, learning control for executing the process in S10 and control data acquired by the learning control will be described.

First, a target trajectory (first trajectory) required for performing learning control is determined in accordance with the starting position and stopping position of driving of the stage 11. The target trajectory may be a trajectory for a maximum stroke of the stage 11. The target trajectory has an acceleration section, a constant speed section, and a deceleration section (different sections in driving). The time period for applying a force to the stage 11 so that the position of the stage 11 may change in an accelerated manner from an initial speed to a predetermined speed will be called an acceleration section. The time period in which the position of the stage 11 changes by a predetermined amount and the stage 11 moves at a predetermined constant speed will be called a constant speed section. Finally, the time period in which a reverse acceleration to that of the acceleration section is applied to the stage 11 from the predetermined speed to the initial speed will be called a deceleration section. The predetermined speed is a maximum speed of the stage 11.

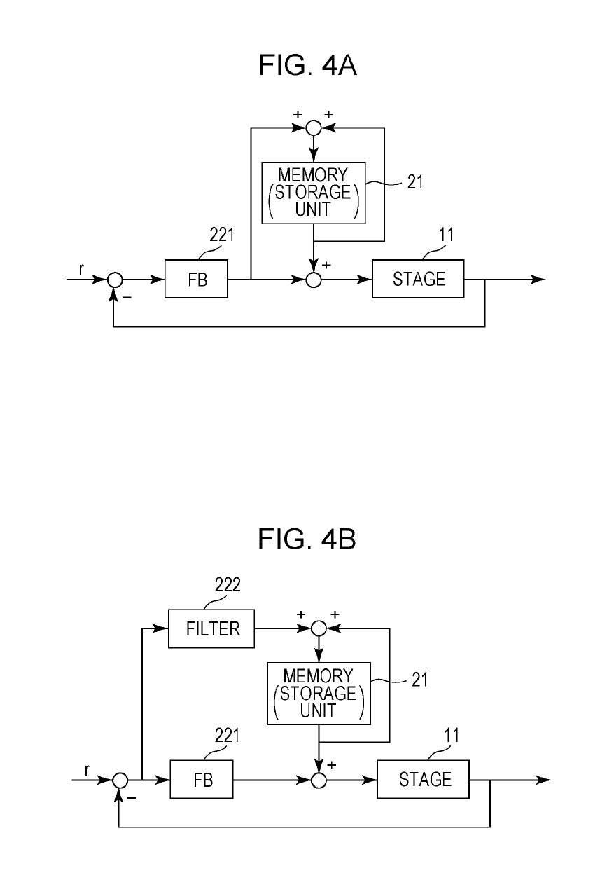

FIG. 4A is a block diagram illustrating functions of the drive control unit 22 and storage unit 21 for driving the stage 11 which is a control target of learning control. FIG. 4A does not illustrate an actuator configured to apply a driving force to the stage 11 and a measuring device configured to measure the position of the stage 11.

A feedback control circuit 221 (hereinafter, called a circuit 221) in the drive control unit 22 outputs a command value to be issued to the stage 11 based on a difference between the position of the stage 11 and a target position (r). Feedback control in the circuit 221 may be PID control, for example. The drive control unit 22 determines control data for inputting a feedforward to the stage 11. In other words, control data in the last trial, which is temporarily stored in the storage unit 21 is added to a command value output from the circuit 221.

When the stage 11 is driven for the first time, the storage unit 21 stores control data in which command values for an elapsed time are all zero as an initial control data set. After the first trial is performed, command values each for a difference between the target position (r) and a response position of the stage 11 are output from the circuit 221, and the output command values are sequentially stored in the storage unit 21. In the second trial, the drive control unit 22 adds the command values output secondly from the circuit 221 to the control data stored in the storage unit 21 in the first trial to acquire a new control data set. The control data set is overwritten and is stored within the storage unit 21 and is input to the stage 11 as a feedforward.

In the same manner, in the Nth (N≧3) trial, the drive control unit 22 adds command values from the circuit 221 and control data stored in the storage unit 21 in the (N−1)th trial. The result is stored in the storage unit 21 as a control data set to be used in the (N+1)th trial and is input to the stage 11. The drive control unit 22 repeats a predetermined number of trials and then stores the resulting control data set to the storage unit 21. Alternatively, the learning control stops when it is determined that the control data set hardly change through the repetition of trials, and the acquired control data set may be stored in the storage unit 21.

By performing such learning control, the drive control unit 22 acquires a control data set having a reduced control error with respect to a target trajectory. Particularly, such a correction effect may be achieved independent of factors such as a reproducible quantization error and a reproducible error that is difficult to correct by a control model build for a correction calculation. For example, influences of repetitively occurring disturbances according to positions may be cancelled, such as a stress caused by a distribution cable connected to the stage 11 and uneven thrust of an actuator driving the stage 11.

The stage 11 involves a delay in drive response to a command value in accelerating and decelerating. Accordingly, even when the target position (r) of the stage 11 reaches an end of a target trajectory, the drive control unit 22 continues to control by inputting a stopping position of the stage 11 as a target position (r) during a time period until the stage 11 is settled.

The learning control circuit illustrated in FIG. 4A is given for illustration purpose only and may be changed as required. For example, as illustrated in FIG. 4B, data describing a difference between a target position and a position of the stage 11 may be stored in the storage unit 21 before the data are fed to the circuit 221. In that case, the data may be fed to a filter 222 to form waveforms in advance. The data having passed through the filter 222 may exclude an influence of a component included in waveforms exhibiting an irreproducible disturbance and unnecessary to learn and may thus be used for the addition and storage as described above.

A feedforward control circuit may be inserted to the circuit 221. If a command value from the circuit 221 has passed through the feedforward control circuit, the influence of the disturbance may be reduced in advance so that the number of times of execution of learning control may be reduced.

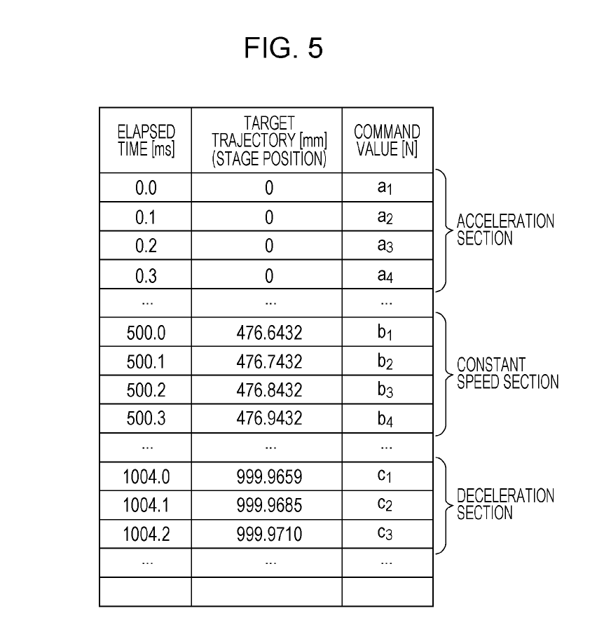

FIG. 5 is a table of control data acquired by learning control performed by the drive control unit 22. The control data may be acquired by driving the stage 11 at a maximum speed of 1 m/s such that the total moving distance in a single axis direction may be equal to 1 m. The control data has an elapsed time (ms) from a starting time of driving and a command value (N). The command values are acquired in the last trial in learning control performed by the drive control unit 22 for elapsed times. For use in processes, which will be described below, positions (mm) of a target trajectory corresponding to elapsed times may be stored. The storage unit 21 may store the elapsed times at intervals each equal to a sampling interval of a digital control system or may thin out elapsed times for reduced amount of data.

Referring back to FIG. 3, S20 to S50 (where S stands for “step”) will be described below. The generating unit 20 determines a new target trajectory (second trajectory) (S20). The trajectory in a constant speed section of the target trajectory overlaps a part of a constant speed section trajectory of the target trajectory under learning control. A new target trajectory is generated in accordance with the driving start position and stop position of the stage 11.

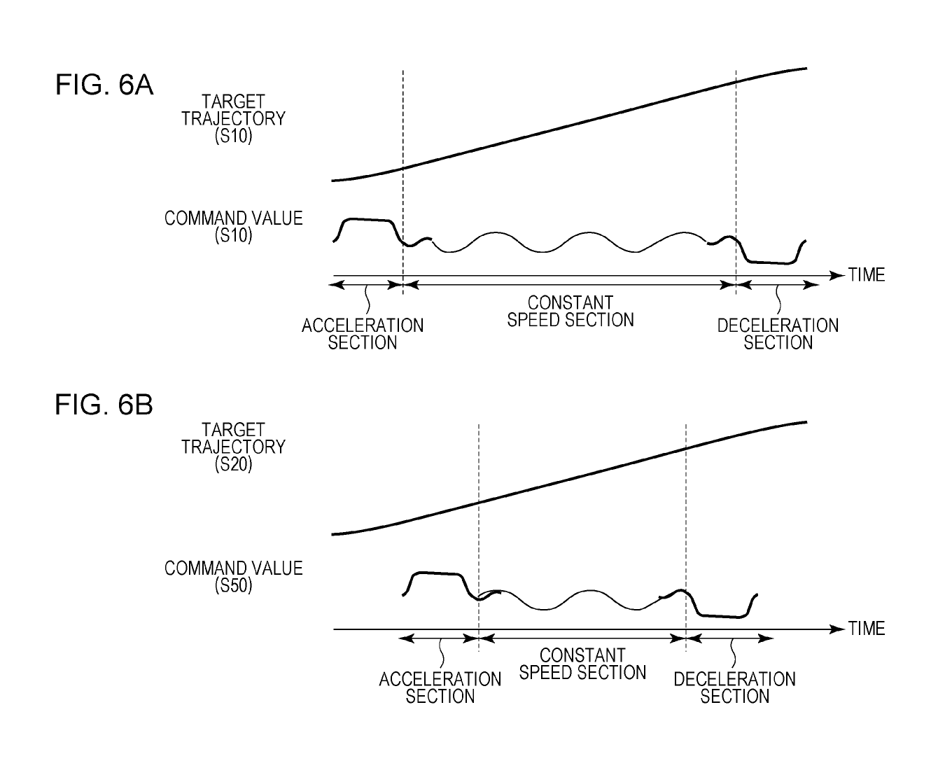

S30 to S50 correspond to the process for generating a control data set for a new target trajectory by using the control data set illustrated in FIG. 5. FIG. 6A is a graph illustrating the control data set illustrated in FIG. 5. FIG. 6B is a graph regarding a control data set to be newly generated. While a trajectory of the constant speed section in the target trajectory generated in S20 is matched with a trajectory of a part of the constant speed section of the target trajectory in S10, the driving start position and stop position of the target trajectory generated in S20 are different from the driving start position and stop position of the target trajectory in S10.

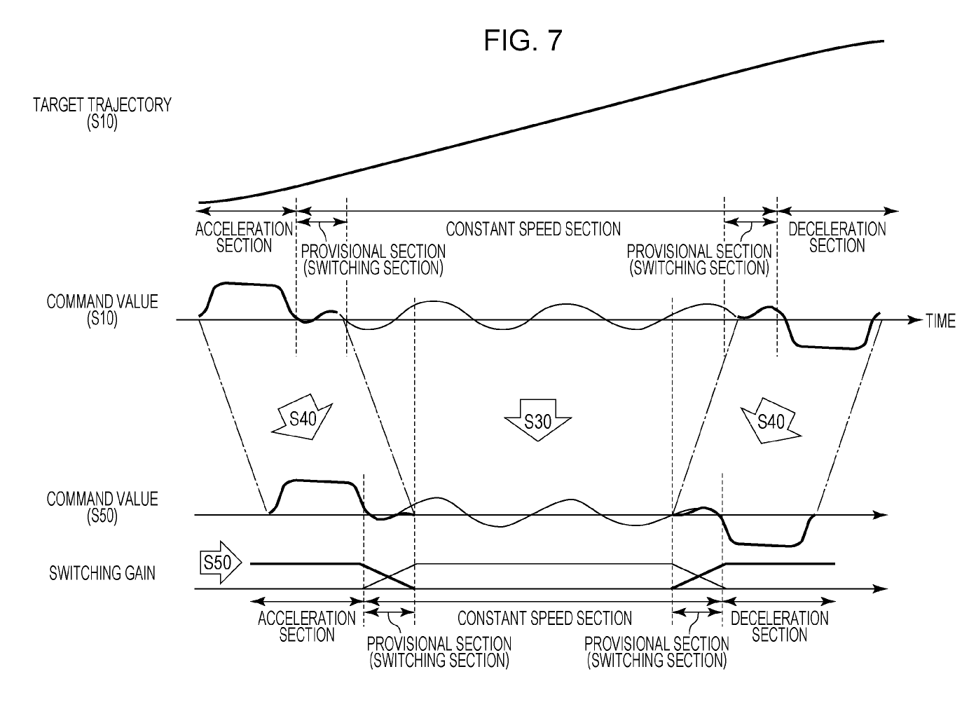

FIG. 7 schematically illustrates a method for generating a control data set for a new target trajectory by using the control data set acquired by performing learning control. First, the generating unit 20 acquires data regarding a constant speed section of a control data set to be newly generated (S30). Command values for positions corresponding to the positions in the constant speed section of the target trajectory acquired in S20 are acquired from the control data set acquired in S10.

Subsequently, the generating unit 20 acquires command values corresponding to elapsed times in an acceleration section and a deceleration section from the control data set acquired in S10 (S40). Here, control data for a time period corresponding to a delay of a control response to each of acceleration and deceleration (hereinafter, called a settling time) is also acquired in advance from control data for the constant speed section.

The data acquired in S30 and S40 are combined (connection process) (S50). Smooth connection between control data for a section having an acceleration and control data for the constant speed section may be required. Switching section is a section for switching between the data for the acceleration section (or deceleration) and a part of the data for the constant speed section. Accordingly, control data for the constant speed section corresponding to the settling time, which are acquired along with the control data for the acceleration section, is also used on the starting point side of the data for the constant speed section, which are acquired in S30. Control data for the constant speed section corresponding to the settling time, which are acquired along with the data for the deceleration section, is used on the end point side of the data for the constant speed section, which are acquired in S30. For a switching section for switching control data for a settling time after an acceleration section (or before a deceleration section) and control data for a constant speed section, a switching gain is set as in (1) and (2).

Connected Control Data=(control data after acceleration section)×(switching gain for acceleration section)+(control data for constant speed section)×(switching gain for constant speed section) (1)

(switching gain for acceleration section)+(switching gain for constant speed section)=1 (2)

For transition from the acceleration section to the constant speed section, for example, the switching gain for the acceleration section is changed from 1 to 0 and, at the same time, the switching gain for the constant speed section is changed from 0 to 1. As described above, the ratio of the control data for a switching section in the acceleration section or deceleration section and the control data for the constant speed section is serially changed for the switching (or the ratio is adjusted). This may prevent reduction of control accuracy for the stage 11 due to discontinuous command values applied to the stage 11.

The same is true for the connection between control data for a constant speed section and control data for a deceleration section. After the connection, the value of the elapsed time is changed properly by setting the data starting time as an elapsed time 0. The connected control data may be generated before the stage 11 is driven or may be generated sequentially during the driving. Performing the connection in parallel with the driving allows reduction of a standby time.

An excessively long or short switching section may possibly result in a large control error. The last time up to the loss of an influence of an acceleration to the stage 11 may be set as a settling time. For example, the length of a switching section may be within a range equal to or higher than 1 ms and equal to or lower than 50 ms or more and may preferably within a range equal to or higher than 1 ms and equal to or lower than 10 ms. Here, the program illustrated in the flowchart in FIG. 3 completes.

In the disturbance in an acceleration section and a deceleration section, delays of control responses to forces applied for acceleration is dominant over the stress caused by a distribution cable dependent on the position of the stage 11, for example. Delays of the control responses are less dependent on the position of the stage 11 because they are largely influenced by the magnitude of the acceleration and durations of an acceleration section and a deceleration section. Thus, a control data set acquired at a different position may be diverted for a new control data set as far as it is for an acceleration section or a deceleration section. On the other hand, a main error factor in a constant speed section is a disturbance dependent on a position. Therefore, in S30, control data corresponding to the same position may be diverted.

The control data generation method according to this embodiment has been described above. According to this embodiment, a control data set for driving the stage 11 along a newly generated target trajectory may be generated without driving under learning control on the new target trajectory. Like this embodiment, the higher the identity between the length of an acceleration section and the magnitude of acceleration (acceleration condition) of a target trajectory to be generated newly and the length of an acceleration section and the magnitude of acceleration of one target trajectory for long-distance driving under learning control is and the higher the identity between the length of a deceleration section and the magnitude of acceleration (deceleration condition) of a target trajectory to be generated newly and the length of a deceleration section and the magnitude of acceleration of one target trajectory for long-distance driving under learning control is, the more closely control data for driving along the target trajectory may be generated.

In the generation of control data according to this embodiment, the starting position and stopping position of the driving of the stage 11 may be changed. In S50, the control data are generated by using a part of the data acquired by performing learning control in S10. Thus, an effect is provided which causes a control error reduced substantially to the same extent as those of the control data acquired by driving the stage 11 again under learning control.

Because the time for previous learning control may be omitted, the throughput may be improved. Furthermore, because at least one set of control data may be required for an acceleration section and a deceleration section, a reduced space of storage (memory space) may be required, resulting in reduced costs.

### Examples of the First Embodiment

Effects of this exemplary embodiment will be described with reference to simple examples. In a case where the trajectory of the stage 11 is the trajectory illustrated in FIG. 2C, six patterns of the starting position and stopping position of the stage 11 are provided for six chips at a maximum in the y axis direction with a fixed x value. In a case where this embodiment is not applied, control data for the six patterns are acquired by performing learning control six times. When this embodiment is applied, learning control in a case where the stage 11 is driven for six chips may be performed once. Thus, the driving time under other learning control may be reduced, and a less storage space may be required.

Next, a case will be considered in which positions of a plurality of alignment marks on the wafer 10 are measured. In some cases, several tens marks may be measured. It is assumed here that 50 patterns of control data for driving involved in the mark measurement are provided for one axis. When one trial with learning control takes one second and 20 trials are required for acquiring one control data set, acquisition of 50 patterns of control data may take about 16 minutes. Such reduction of time may improve the throughput.

One command value of 2 bytes and control data acquired by sampling at intervals of 0.1 mm on a distance of 1 m require 10000 points×2 bytes×50=1 Mbyte. Applying this embodiment allows reduction of the storage space for one axis may be reduced to about 1/50.

### Second Embodiment

Next, a second embodiment will be described. According to the second embodiment, another method is applied for storing control data generated in S10 in FIG. 3 to reduce the necessary storage space compared with the first embodiment. Because the fundamental order of the control data generation method for a new target trajectory is the same as that on the flowchart in FIG. 3, the description will be omitted.

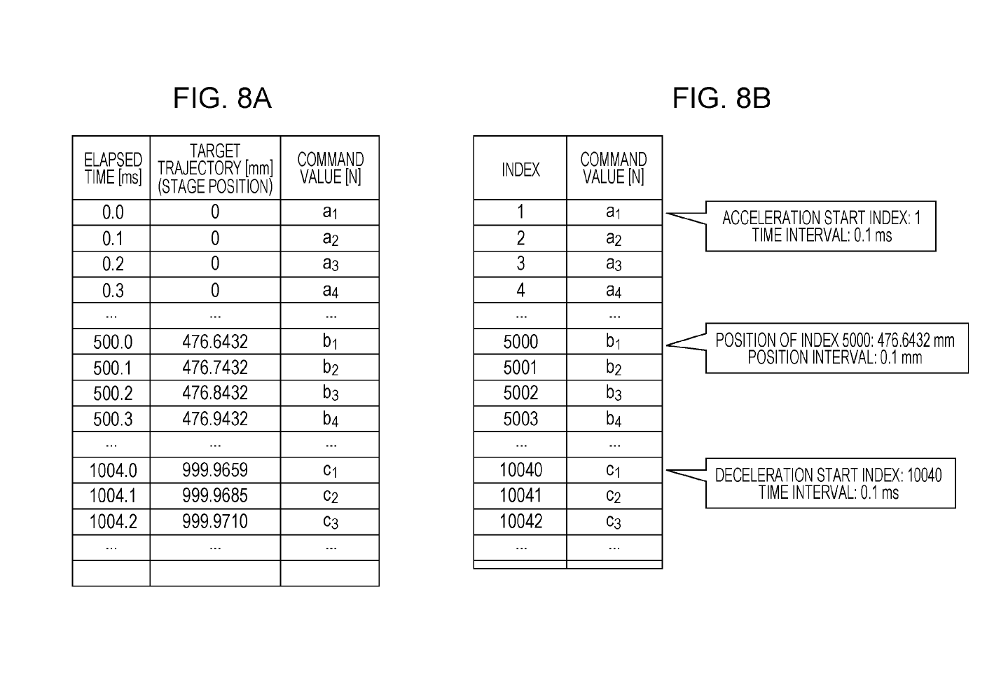

FIG. 8A is a table regarding control data described according to the first embodiment. The generating unit 20 stores sets of an elapsed time, a target trajectory, and a command value in the storage unit 21. On the other hand, FIG. 8B is a table regarding control data stored according to this embodiment. Index numbers (hereinafter, each called an index) (No. 1, 2, . . . ) and command values corresponding thereto are stored in the storage unit 21.

For an acceleration section, information that the index for starting an acceleration section is 1 and information that the time interval indicated by the index is 0.1 ms are stored in the storage unit 21. For a deceleration section, information that the index for starting the deceleration section is 10040 and information that the time interval indicated by the index is 0.1 ms are stored in the storage unit 21. For a constant speed section information that the index for starting the constant speed section is 5000, information that the starting position of the constant speed section is 476.6432 mm, and information that the position interval indicated by the index is 0.1 mm are stored in the storage unit 21.

According to this embodiment, the command values for an acceleration section and a deceleration section may be values for times at equal intervals. Setting equal intervals as described above allows easy correspondence between indices and times based on input time intervals for sampling.

For an acceleration section and a deceleration section, such data may be stored based on a command value corresponding to a time instead of a command value corresponding to a position. This is because the position does not change very much at the start of an acceleration section and at the end of a deceleration section and storing data based on a position may results in a low resolution of control data.

As described above, the storage unit 21 stores information regarding each of the speed sections in addition to indices and command values corresponding to the indices. Here, information regarding each of the speed sections includes an index indicative of a start of the speed section, information (position and time) described by the index, a value of the information upon start of the speed section, and a data interval of information in the speed section. Thus, the amount of data held in the storage unit 21 may be reduced greatly compared with the case where the storage unit 21 stores a set of all of the elapsed time, target trajectory, and command value.

The data intervals in the acceleration section, constant speed section, and deceleration section may be thinned out in a range that the precision of control is not influenced. In a case where the stored data are to be used, data may be complemented as required. This may further reduce the data space required in the storage unit 21. Like the first embodiment, control data for driving the stage 11 along a newly generated target trajectory without driving under learning control on the new target trajectory.

### Other Embodiments

The learning control process (S10) and the target trajectory generation process (S20) may be performed in reverse order. Control data newly generated by the generating unit 20 are not limited to data on a linear target trajectory. Data sets for a plurality of axes may be combined to set a curved trajectory as a target trajectory and thus generate control data using a result of learning control.

For a constant speed section, data corresponding to the same position as that for data for a constant speed section of newly generated control data may be extracted from the control data acquired under learning control. This may reduce an influence of a reproducible disturbance. In a case where the target trajectory of newly generated control data is positionally close to the trajectory under learning control and the influence of a disturbance is within a permissible range, data corresponding to another position may be used.

When the drawing apparatus 100 is powered off, the position of the stage recognizable by the interferometer is unintentionally reset. Accordingly, the drive control unit 22 performs the learning control process (S10) illustrated in FIG. 3 every initialization operation so that the generating unit 20 may again generate control data corresponding to various target trajectories. The same is true for a case where an impact is temporarily applied to the stage.

The drawing apparatus 100 may irradiate a wafer with a plurality of electron beams as in this embodiment or with one electron beam. A lithography apparatus according to the present invention is not limited to a drawing apparatus. The present invention is applicable to an apparatus configured to irradiate a wafer with charged particle beam or ArF laser beam such as an ion beam or a light ray such as extreme ultraviolet light to form a latent image pattern on the wafer and an apparatus configured to form a pattern on a wafer by an imprinting method.

### Article Manufacturing Method

A manufacturing method for an article (such as a semiconductor integrated circuit element, a liquid crystal display element, an image pickup device, a magnetic head, a CD-RW, an optical element, and a photomask) according to an embodiment of the present invention includes a process for forming a pattern on a substrate (such as a wafer and a glass plate) by using the drawing apparatus according to the aforementioned embodiment and a process for performing at least one of etching process and ion implanting process on the wafer having a pattern thereon. The method may further include other well known processes (such as development, oxidation, film forming, vapor deposition, flattening, resist stripping, dicing, bonding, and packaging).

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-133284, filed Jun. 27, 2014, which is hereby incorporated by reference herein in its entirety.

What is claimed is:

1. A command data generation method comprising the steps of:
acquiring, by performing iterative learning control on a moving member, a first command data set for moving the moving member along a first trajectory, the first command data set including data corresponding to an acceleration section, a constant speed section and a deceleration section of the moving member; and
generating a second command data set for driving the moving member along a second trajectory by using a part of data for the constant speed section in the first command data set.

2. The command data generation method according to claim 1, wherein the generating includes generating the second command data set by using data for the acceleration section and data for the deceleration section in the first command data.

3. The command data generation method according to claim 2, wherein the data for the acceleration section are data describing command information corresponding to an elapsed time.

4. The command data generation method according to claim 2, wherein the data for the deceleration section are data describing command information corresponding to an elapsed time.

5. The command data generation method according to claim 1, wherein the part of data for the constant speed section are data describing command information corresponding to a position.

6. The command data generation method according to claim 1, wherein
a trajectory corresponding to the constant speed section of the second command data of the second trajectory overlaps a part of a trajectory corresponding to the constant speed section of the first command data of the first trajectory.

7. The command data generation method according to claim 2, wherein
the generating includes a connection process in a switching section for switching between the data for the acceleration section and a part of the data for the constant speed section.

8. The command data generation method according to claim 2, wherein the generating includes a connection process in a switching section for switching between the data for the deceleration section and a part of the data for the constant speed section.

9. The command data generation method according to claim 7, wherein the connection process includes adjusting a ratio of data to be used for the switching section.

10. The command data generation method according to claim 8, wherein the connection process includes adjusting a ratio of data to be used for the switching section.

11. The command data generation method according to claim 1, further comprising
storing the first command data acquired by the acquiring, wherein
the storing includes storing an index, command information corresponding to the index, and information regarding speed sections including data for the acceleration section, data for the deceleration section, and data for the constant speed section.

12. The command data generation method according to claim 2, wherein the second command data set is data for driving the moving member along the second trajectory by using the same conditions as an acceleration condition and a deceleration condition for driving the moving member along the first trajectory.

13. A positioning apparatus comprising:
a moving member; and
a drive control unit configured to control positioning of the moving member based on a second command data set,
wherein the second command data set is generated by using a part of data for a constant speed section of the first command data set which is acquired by performing iterative learning control on the moving member.

14. The positioning apparatus according to claim 13, the second command data set is generated by using data for an acceleration section and data for a deceleration section of the first command data set.

15. A lithography apparatus having a moving member for irradiating a beam to a substrate to form a pattern on the substrate, the apparatus comprising:
a drive control unit configured to control positioning of the moving member based on the second command data set,
wherein the second command data set is generated by using a part of data for a constant speed section of the first command data set which is acquired by performing iterative learning control on the moving member.

16. An article manufacturing method comprising the steps of:
irradiating a beam to a substrate by using a lithography apparatus; and
performing at least one of an etching process and ion implanting process on the substrate, wherein
the lithography apparatus has:
a moving member; and
a drive control unit configured to control positioning of the moving member based on a second command data set,
wherein the second command data set is generated by using a part of data for a constant speed section of the first command data set which is acquired by performing iterative learning control on the moving member.
